(19) United States
(12) Patent Application Publication
(10) Pub. No.: US 2009/0273031 A1
(43) Pub. Date: Nov. 5, 2009

(54) SEMICONDUCTOR DEVICE

(75) Inventors: Wataru SAITO, Kanagawa-ken (JP); Syotaro ONO, Kanagawa-ken (JP); Nana HATANO, Kanagawa-ken (JP); Masakatsu TAKASHITA, Kanagawa-ken (JP); Hiroshi OHTA, Hyogo-ken (JP); Miho WATANABE, Tokyo (JP)

Correspondence Address: PATTERSON & SHERIDAN, L.L.P., 3040 POST OAK BOULEVARD, SUITE 1500, HOUSTON, TX, 77056, US

(73) Assignee: KABUSHIKI KAISHA TOSHIBA, Tokyo (JP)

(21) Appl. No.: 12/408,415

(22) Filed: Mar. 20, 2009

(30) Foreign Application Priority Data
May 2, 2008 (JP) 2008120309

(51) Int. Cl. H01L 29/78

(52) U.S. Cl. 257/339; 257/E29.257

(57) ABSTRACT

A semiconductor device includes: a first semiconductor layer of a first conductivity type; a second semiconductor layer of the first conductivity type provided on a major surface of the first semiconductor layer; a third semiconductor layer of a second conductivity type provided on the major surface of the first semiconductor layer, the third semiconductor layer forming a structure of periodical arrangement with the second semiconductor layer; a fourth semiconductor layer of the second conductivity type provided above the third semiconductor layer; a fifth semiconductor layer of the first conductivity type selectively provided on a surface of the fourth semiconductor layer; a first main electrode electrically connected to the first semiconductor layer; a second main electrode provided to contact a surface of the fifth semiconductor layer and a surface of the fourth semiconductor layer; and a control electrode provided above the fifth semiconductor layer, the fourth semiconductor layer, and the second semiconductor layer via an insulative film. A portion is provided locally in the third semiconductor layer, the portion depleting at a voltage not more than one third of a voltage at which the second semiconductor layer and the third semiconductor layer completely deplete.

### CROSS-REFERENCE TO RELATED APPLICATIONS

This application is based upon and claims the benefit of priority from the prior Japanese Patent Application No. 2008-120309, filed on May 2, 2008; the entire contents of which are incorporated herein by reference.

### BACKGROUND OF THE INVENTION

1. Field of the Invention

The present invention relates to a semiconductor device used In power control.

2. Background Art

The ON resistance of a vertical power MOSFET (Metal Oxide Semiconductor Field Effect Transistor) greatly depends on the electrical resistance of the conduction layer (drift layer). The impurity concentration that determines the electrical resistance of the drift layer cannot be increased above a limit according to the breakdown voltage of the pn junction formed by the base layer and the drift layer. Therefore, a tradeoff relationship exists between the device breakdown voltage and the ON resistance. It is important to improve this tradeoff in devices of low power consumption. The tradeoff includes a limit determined by the device material. Overcoming this limit leads to the realization of a low ON resistance device superior to existing power devices.

To solve these problems, a known example of a power MOSFET includes a p-type pillar layer and an n-type pillar layer buried in the drift layer in a structure called a “super junction structure” (for example, JP-A 2006-179598 (Kokai)). The super junction structure has the same amount of charge (impurity amount) in the p-type pillar layer and the n-type pillar layer and thereby creates a pseudo-non-doped layer, holds a high breakdown voltage, and passes a current through the highly doped n-type pillar layer to realize a low ON resistance superior to that of the material limit.

The ON resistance can be reduced by a narrower horizontal period of the super junction structure. However, reducing the chip area as the ON resistance is reduced unfortunately increases the operating drain current density. As the drain voltage is increased to produce a large drain current, a depletion layer extends from the junction of the p-type pillar layer and the n-type pillar layer of the super junction structure; the n-type pillar layer unfortunately is pinched off; and the current saturates. Consequently, a high operating current density cannot be obtained. Even in the case where the ON resistance is reduced, the chip surface area therefore cannot be reduced.

### SUMMARY OF THE INVENTION

According to an aspect of the invention, there is provided a semiconductor device including: a first semiconductor layer of a first conductivity type; a second semiconductor layer of the first conductivity type provided on a major surface of the first semiconductor layer; a third semiconductor layer of a second conductivity type provided adjacent to the second semiconductor layer on the major surface of the first semiconductor layer, the third semiconductor layer forming a structure of periodical arrangement with the second semiconductor layer along a horizontal direction substantially parallel to the major surface of the first semiconductor layer; a fourth semiconductor layer of the second conductivity type provided above the third semiconductor layer; a fifth semiconductor layer of the first conductivity type selectively provided on a surface of the fourth semiconductor layer; a first main electrode electrically connected to the first semiconductor layer; a second main electrode provided to contact a surface of the fifth semiconductor layer and a surface of the fourth semiconductor layer; and a control electrode provided above the fifth semiconductor layer, the fourth semiconductor layer, and the second semiconductor layer via an insulative film, a portion being provided locally in the third semiconductor layer, the portion depleting at a voltage not more than one third of a voltage at which the second semiconductor layer and the third semiconductor layer completely deplete.

According to another aspect of the invention, there is provided a semiconductor device including: a first semiconductor layer of a first conductivity type; a second semiconductor layer of the first conductivity type provided on a major surface of the first semiconductor layer; a third semiconductor layer of a second conductivity type provided adjacent to the second semiconductor layer on the major surface of the first semiconductor layer, the third semiconductor layer forming a structure of periodical arrangement with the second semiconductor layer along a horizontal direction substantially parallel to the major surface of the first semiconductor layer; a fourth semiconductor layer of the second conductivity type provided above the third semiconductor layer; a fifth semiconductor layer of the first conductivity type selectively provided on a surface of the fourth semiconductor layer; a first main electrode electrically connected to the first semiconductor layer; a second main electrode provided to contact a surface of the fifth semiconductor layer and a surface of the fourth semiconductor layer; and a control electrode provided above the fifth semiconductor layer, the fourth semiconductor layer, and the second semiconductor layer via an insulative film, the third semiconductor layer being formed in a striped planar pattern; and the third semiconductor layer being divided in a depth direction at a portion intermediate along the depth direction by the second semiconductor layer to provide a portion where the third semiconductor layer partially does not exist.

### BRIEF DESCRIPTION OF THE DRAWINGS

FIG. 1A a cross-sectional view of main components of a semiconductor device according to a first embodiment of the invention, and FIG. 1B is an impurity concentration profile along the vertical direction (depth direction) of the portion illustrated in FIG. 1 A;

FIG. 2 is a cross-sectional view of main components of a semiconductor device of a comparative example illustrating the extension of a depletion layer on the ON state;

FIG. 3 is a cross-sectional view of main components of a semiconductor device according to the first embodiment illustrating the extension of a depletion layer on the ON state;

FIG. 4 is a graph illustrating the relationship between drain current density and ON resistance by comparing the semiconductor device according to the first embodiment with the comparative example illustrated in FIG. 2;

FIG. 5 is a graph illustrating the relationship between a ratio (Na/Nb) of an impurity concentration of a p⁻ region to an impurity concentration of a p-type pillar layer and a permissible current density (A/cm²) for the semiconductor device according to the first embodiment;

FIG. 6 is a graph illustrating the relationship between a ratio (t/W) of a thickness t of the p⁻ region to a width W of the p-type pillar layer and the permissible current density (A/cm²) for the semiconductor device according to the first embodiment;

FIG. 7A is a cross-sectional view of main components of a semiconductor device according to a second embodiment of the invention, FIG. 7B is an impurity concentration profile along the vertical direction (depth direction) of the portion illustrated in FIG. 7A and FIG. 7C is an electric field distribution diagram in the vertical direction (depth direction);

FIG. 8A is a cross-sectional view of main components of the structure of a modification of the second embodiment of the invention, FIG. 8B is an impurity concentration profile along the vertical direction (depth direction) of the portion illustrated in FIG. 8A and FIG. 8C is an electric field distribution diagram in the vertical direction (depth direction);

FIG. 9A is a cross-sectional view of main components of the structure of another modification of the second embodiment of the invention, FIG. 9B is an impurity concentration profile along the vertical direction (depth direction) of the portion illustrated in FIG. 9A;

FIG. 10A is a cross-sectional view of main components of a semiconductor device according to a third embodiment of the invention, and FIG. 10B is an impurity concentration profile along the vertical direction (depth direction) of the portion illustrated in FIG. 10A;

FIG. 11A is a cross-sectional view of main components of the structure of a modification of the third embodiment of the invention, and FIG. 11B is an impurity concentration profile along the vertical direction (depth direction) of the portion illustrated in FIG. 11A;

FIG. 12A is a cross-sectional view of main components of the structure of another modification of the third embodiment of the invention, and FIG. 12B is an impurity concentration profile along the vertical direction (depth direction) of the portion illustrated in FIG. 12A;

FIG. 13A is a cross-sectional view of main components of a semiconductor device according to a fourth embodiment of the invention, and FIG. 13B is an impurity concentration profile along the vertical direction (depth direction) of the portion illustrated in FIG. 13A;

FIG. 14A is a cross-sectional view of main components of the structure of a modification of the fourth embodiment of the invention, and FIG. 14B is an impurity concentration profile along the vertical direction (depth direction) of the portion illustrated in FIG. 14A;

FIG. 15A is a cross-sectional view of main components of the structure of another modification of the fourth embodiment of the invention, and FIG. 15B is an impurity concentration profile along the vertical direction (depth direction) of the portion illustrated in FIG. 15A;

FIG. 16A is a cross-sectional view of main components of the structure of still another modification of the fourth embodiment of the invention, and FIG. 16B is an impurity concentration profile along the vertical direction (depth direction) of the portion illustrated in FIG. 16A;

FIG. 17A is a cross-sectional view of main components of the structure of still another modification of the fourth embodiment of the invention, and FIG. 17B is an impurity concentration profile along the vertical direction (depth direction) of the portion illustrated in FIG. 17A;

FIG. 18A is a cross-sectional view of main components of the structure of still another modification of the fourth embodiment of the invention, and FIG. 18B is an impurity concentration profile along the vertical direction (depth direction) of the portion illustrated in FIG. 18A;

FIG. 19A is a cross-sectional view of main components of a semiconductor device according to a fifth embodiment of the invention, and FIG. 19B is an impurity concentration profile along the vertical direction (depth direction) of the portion illustrated in FIG. 19A; and

FIG. 20A is a top view illustrating a planar layout of the n-type pillar layer 2 and the p-type pillar layer 3 of a semiconductor device according to a sixth embodiment of the present invention, FIG. 20B is a cross-sectional view along A-A′ of FIG. 20A. FIG. 20C is a cross-sectional view along B-B′ of FIG. 20A, and FIG. 20D is a cross-sectional view along C-C′ of FIG. 20A.

### DETAILED DESCRIPTION OF THE INVENTION

Embodiments of the present invention will now be described with reference to the drawings. In the embodiments of the present invention, a MOSFET including, for example, a planar gate structure, is described as an example of a semiconductor device. In the embodiments below, a first conductivity type is assumed to be an n-type, and a second conductivity type is assumed to be a p-type. Like elements in the drawings are marked with like reference numerals.

### First Embodiment

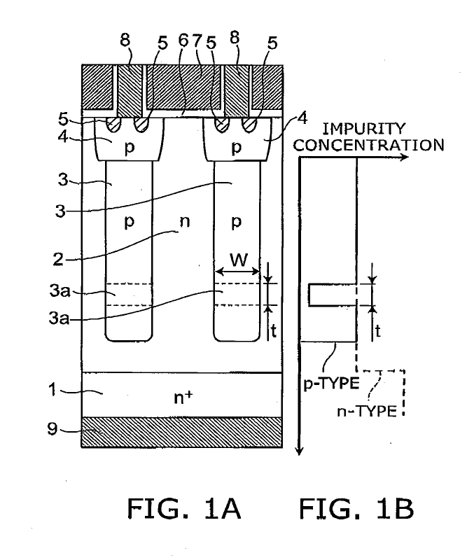

FIG. 1A is a cross-sectional view of main components of a semiconductor device according to a first embodiment of the present invention, FIG. 1B is an impurity concentration profile along the vertical direction (depth direction) of the portion illustrated in FIG. 1A. In FIG. 1B, the solid line represents a concentration profile of the p-type impurity; and the broken line represents a concentration profile of the n-type impurity.

The semiconductor device according to this embodiment includes a vertical device having a main current path formed in a vertical direction to connect a second main electrode 8 and a first main electrode 9 provided on top and bottom surfaces of a semiconductor layer, respectively. The semiconductor device according to this embodiment includes a cell section in which the main current path is formed, and a terminal section formed on an exterior of the cell section to surround the cell section. FIG. 1A illustrates a portion of the cell section.

A drain layer 1 is provided as a first semiconductor layer made of n⁺-type silicon having a high impurity concentration. An n-type pillar layer 2, which is a second semiconductor layer made of n-type silicon, and a p-type pillar layer 3, which is a third semiconductor layer made of p-type silicon, are provided on a major surface of the drain layer 1.

The n-type pillar layer 2 and the p-type pillar layer 3 are arranged alternately adjacent (as a pn junction) and periodically along a horizontal direction substantially parallel to the major surface of the drain layer 1, forming a so-called “super junction structure.” A bottom of the n-type pillar layer 2 contacts the drain layer 1, forming a portion of the main current path in the ON state.

The planar pattern of the structure of periodical arrangement of the n-type pillar layer 2 and the p-type pillar layer 3 (super junction structure) has, for example, a striped configuration, but is not limited thereto, and may be formed in a lattice configuration or a staggered configuration.

A base layer 4 made of p-type silicon is provided, as a fourth semiconductor layer, above the p-type pillar layer 3. The base layer 4 is adjacent to the n-type pillar layer 2 and forms a pn junction similar to the p-type pillar layer 3. A source region 5 made of n⁺-type silicon is provided selectively, as a fifth semiconductor layer, on a surface of the base layer 4.

A gate insulation film 6 is provided above a portion that extends from the n-type pillar layer 2 along the base layer 4 to the source region 5. The gate insulation film 6 is, for example, a silicon oxide film having a film thickness of about 0.1 μm. A gate electrode 7, i.e., a control electrode, is provided above the gate insulation film 6.

A source electrode 8 is provided, as a second main electrode, above a portion of the source region 5 and above a portion of the base layer 4 interposed between the source regions 5. The source electrode 8 contacts and electrically connects to a surface of the source region 5 and a surface of the base layer 4. A drain electrode 9 is provided, as a first main electrode, on a surface of the drain layer 1 on a side opposite to the major surface. The drain electrode 9 is electrically connected to the drain layer 1.

When a prescribed voltage is applied to the gate electrode 7, a channel is formed in a portion of a top layer of the base layer 4 directly below the gate electrode 7; and the source region 5 and the n-type pillar layer 2 become electrically connected. As a result, current flows between the source electrode 8 and the drain electrode 9 via the source region 5, the n-type pillar layer 2, and the drain layer 1; and the semiconductor device is switched to an ON state.

Further, in the super junction structure in the OFF state, a depletion layer extends from the pn junction of the pn pillar layers 3 and 2 in a state where a high voltage is applied to the drain electrode 9; and the high breakdown voltage can be held.

Here, as a comparative example, the case is considered where the impurity concentration of the p-type pillar layer 3 is constant in the depth direction. As the drain voltage applied in the ON state is increased, the drain current increases; but a voltage drop occurs due to resistance of the n-type pillar layer 2. The potential of the p-type pillar layer 3 is the source potential, and the n-type pillar layer 2 has a potential gradient according to the voltage drop. In other words, a portion of the n-type pillar layer 2 proximal to the drain electrode 9 has the drain potential or a potential close thereto; while the more proximal a portion is to the source electrode 8 side, the more the potential of the portion decreases from the drain potential.

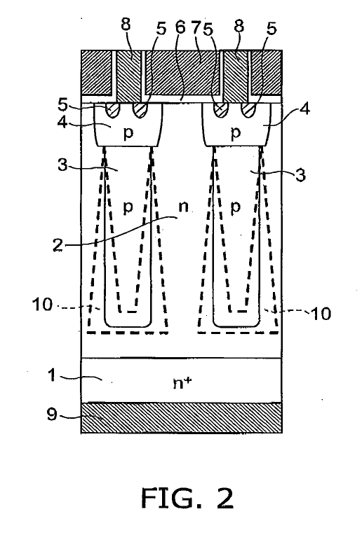

Therefore, a voltage corresponding to the drain voltage is applied to the junction between the p-type pillar layer 3 and the n-type pillar layer 2 at the lower side (drain electrode 9 side) of the super junction structure. As illustrated by the broken line in FIG. 2, the more proximal to the lower side of the super junction structure, the more the applied voltage causes a depletion layer 10 to extend in the horizontal direction. In the case where the n-type pillar layer 2 is completely depleted by the depletion layer 10 extending from the p-type pillar layers 3 on either side of the n-type pillar layer 2, a pinch-off state is reached, and the drain current saturates. That is, a current exceeding the saturation current cannot flow; and the pinch off determines the limit of the operating current density.

Conversely, in this embodiment illustrated in FIGS. 1A and 1B, a p⁻ region 3a is provided in a portion of the p-type pillar layer 3 at the drain electrode 9 side and depletes at a voltage not more than one third of the voltage at which the n-type pillar layer 2 and the p-type pillar layer 3 completely deplete. Thus, the p⁻ region 3a depletes at a voltage not more than one third of the voltage at which other portions of the p-type pillar layer 3 completely deplete.

As illustrated by the solid line in FIG. 1B, the impurity concentration of the p-type pillar layer 3 is locally lower at the portion on the drain electrode 9 side than at other portions. The portion of the p-type pillar layer 3 on the side below the p⁻ region 3a (drain electrode 9 side) and the portion of the p-type pillar layer 3 on the side above the p⁻ region 3a (source electrode 8 side) have an impurity concentration higher than that of the p⁻ region 3a and are constant along the depth direction.

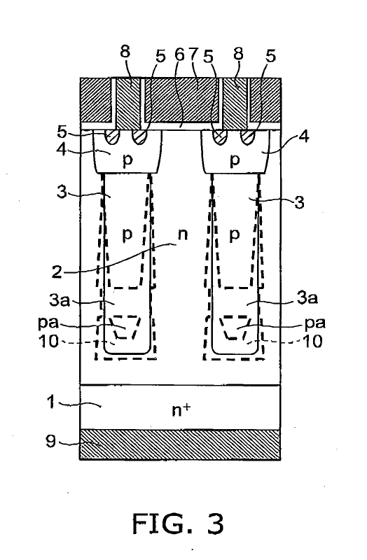

The spread of the depletion layer 10 in the ON state for the structure of this embodiment is illustrated by the broken line in FIG. 3. As the drain voltage is increased in the ON state, the p⁻ region 3a recited above, which has a locally low impurity concentration, depletes prior to the n-type pillar layer 2 in the portion where the p⁻ region 3a is provided. The complete depletion of the p⁻ region 3a divides the source potential of the p-type pillar layer 3 in the vertical direction, results in a smaller potential difference between a lower portion pa of the p-type pillar layer 3 on the side below the p⁻ region 3a and the n-type pillar layer 2 adjacent thereto, and inhibits the extension of the depletion layer toward the n-type pillar layer 2. As a result, pinch off of the n-type pillar layer 2, which is the current path in the ON state, can be inhibited; and a high operating current density can be realized.

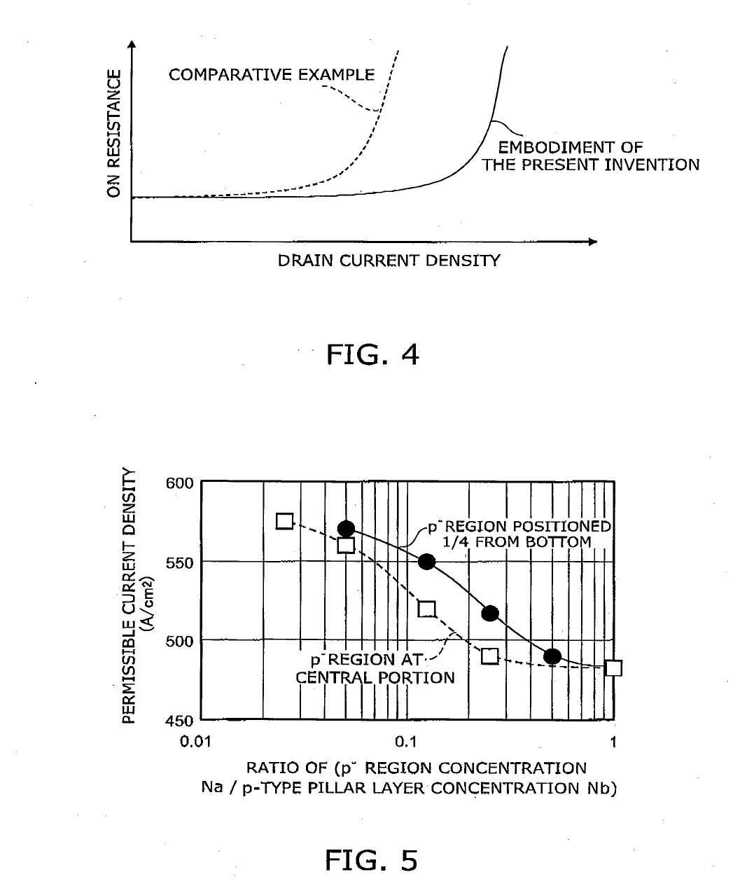

FIG. 4 is a graph illustrating the relationship between drain current density and ON resistance by comparing the comparative example (constant impurity concentration of the p-type pillar layer in the depth direction) with this embodiment of the present invention illustrated in FIGS. 1A and 1B and FIG. 3.

As illustrated in FIG. 4, the drain current density at which saturation occurs is higher for this embodiment than for the comparative example. Thus, a high operating drain current density for this embodiment is possible at a low ON resistance.

Pinch off of the n-type pillar layer 2 occurs readily on the side proximal to the drain electrode 9. Therefore, it is favorable that the p⁻ region 3a, in which the impurity concentration of the p-type pillar layer 3 is locally lower, is formed at a position that is more proximal to the drain electrode 9 in the depth direction than is the central portion of the p-type pillar layer 3.

FIG. 5 is a graph illustrating the relationship between Na/Nb and a permissible current density (A/cm²). Na represents the impurity concentration of the p⁻ region 3a. Nb represents the impurity concentration of a portion of the p-type pillar layer 3 other than the p⁻ region 3a. In FIG. 5, the solid line (•) represents the case where the p⁻ region 3a is provided at a position one fourth of the p-type pillar layer 3 from the bottom in the depth direction; and the broken line (□) represents the case where the p⁻ region 3a is provided at a central portion of the p-type pillar layer 3 in the depth direction.

In the case where the p⁻ region 3a does not deplete at a low voltage, an increased current density cannot be obtained. Therefore, referring to FIG. 5, it is favorable to set Na/Nb from 1/40 to ½ (0.025<Na/Nb<0.5). A p⁻ region 3a provided at a position one fourth of the p-type pillar layer 3 from the bottom (represented by the solid line) enables a higher current density than a p⁻ region 3a provided at the central portion of the p-type pillar layer 3 (represented by the broken line).

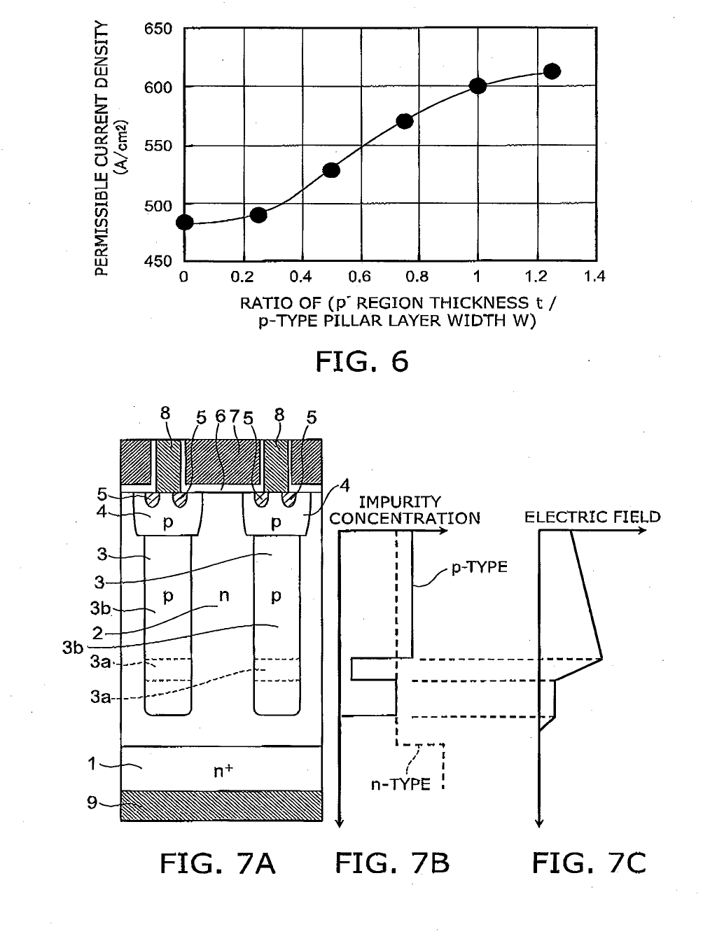

FIG. 6 is a graph illustrating the relationship between t/W and the permissible current density (A/cm²). As illustrated in FIG. 1, t represents the thickness of the p⁻ region 3a, and W represents the width of the p-type pillar layer 3 (equal to the width of the p⁻ region 3a).

A thin p⁻ region 3a, which has a locally low impurity concentration, does not deplete readily. Therefore, referring to FIG. 6, it is favorable to set t/W from ½ to 1 (0.5<t/W<1).

### Second Embodiment

FIG. 7A is a cross-sectional view of main components of a semiconductor device according to a second embodiment of the present invention. FIG. 7B is an impurity concentration profile along the vertical direction (depth direction) of the portion illustrated in FIG. 7A. FIG. 7C is an electric field distribution diagram in the vertical direction (depth direction). In FIG. 7B, the solid line represents a concentration profile of the p-type impurity; and the broken line represents a concentration profile of the n-type impurity.

In the structure illustrated in FIG. 7A, the p-type pillar layer 3 includes a portion 3b on the source electrode 8 side above the p⁻ region 3a. While the p⁻ region 3a has a locally low impurity concentration, the portion 3b has an impurity concentration higher than the impurity concentration of the n-type pillar layer 2 as illustrated in FIG. 7B.

Therefore, the electric field distribution illustrated in FIG. 7C gradually increases from the p-type base layer 4 side toward the p⁻ region 3a and exhibits a peak near the p⁻ region 3a; and the electric field of the lower portion of the base layer 4 can be reduced. Thus, reducing the electric field below the base layer 4 enables avalanche breakdown to occur not directly below the base layer 4 but in the p-type pillar layer 3. Thereby, a stable breakdown voltage can be obtained. Even in the case where a large current flows due to avalanche breakdown, the electric field below the base layer 4 is weak. Consequently, negative resistance does not occur readily, and a high avalanche withstanding capability is obtained.

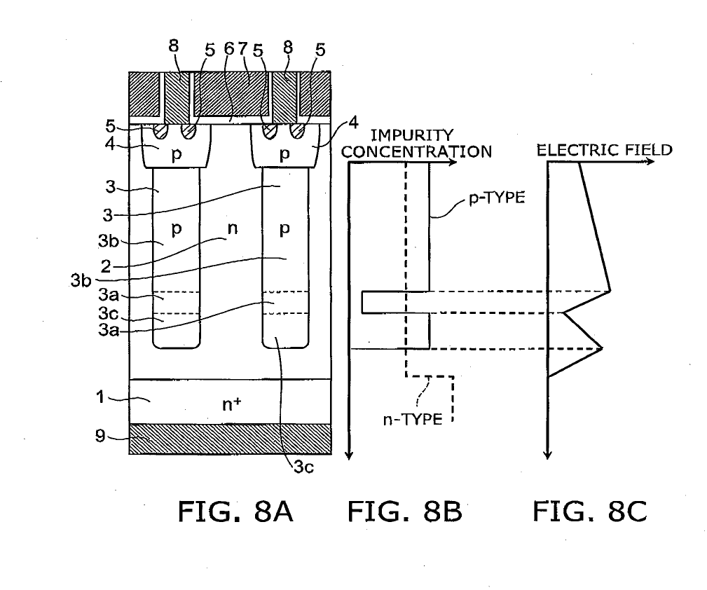

In the structure illustrated in FIGS. 8A to 8C, the p-type pillar layer 3 at the drain electrode 9 side below the p⁻ region 3a, which has a locally low concentration, includes a portion 3c which also has an impurity concentration higher than the impurity concentration of the n-type pillar layer 2 as illustrated in FIG. 8B. Hence, the electric field at the drain electrode 1 side is stronger than that of the p⁻ region 3a as illustrated in FIG. 8C. Thus, the voltage held by the n-type pillar layer 2 and the p-type pillar layer 3 is high and the breakdown voltage can be increased.

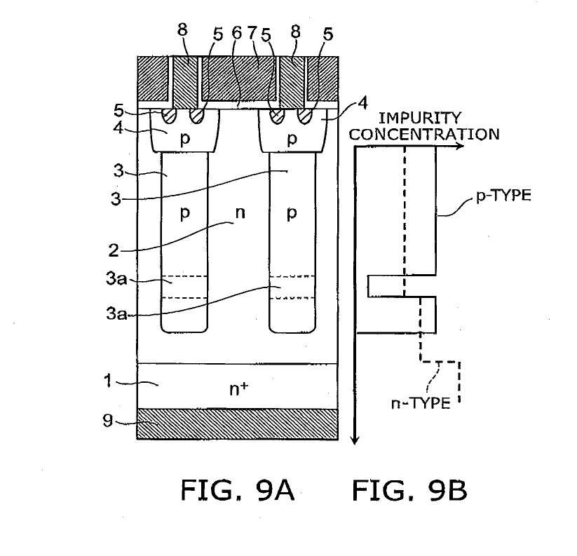

As illustrated in FIGS. 9A to 9B, the impurity concentration of the portion of the n-type pillar layer 2 toward the drain electrode 9 side from the p⁻ region 3a of the p-type pillar layer 3 may be increased higher than the impurity concentration of the portion toward the source electrode 8 side from the p⁻ region 3a. Thereby, the depletion layer does not readily extend into the lower portion of the n-type pillar layer 2 of the drain electrode 9 side, and operation is possible at a higher current density.

### Third Embodiment

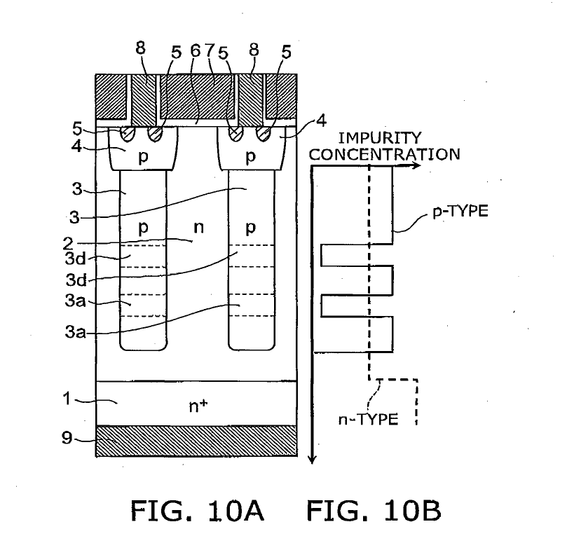

FIG. 10A is a cross-sectional view of main components of a semiconductor device according to a third embodiment of the present invention. FIG. 10B is an impurity concentration profile along the vertical direction (depth direction) of the portion illustrated in FIG. 10A. In FIG. 10B, the solid line represents a concentration profile of the p-type impurity; and the broken line represents a concentration profile of the n-type impurity.

In the structure illustrated in FIGS. 10A and 10B, the p-type pillar layer 3 includes p⁻ regions 3a and 3d formed in two locations having locally low impurity concentrations. The p⁻ regions 3a and 3d are separated from each other in the depth direction. Such a structure further inhibits the n-type pillar layer 2 from depleting, even more so than the structures illustrated heretofore; and a higher operating current density is possible.

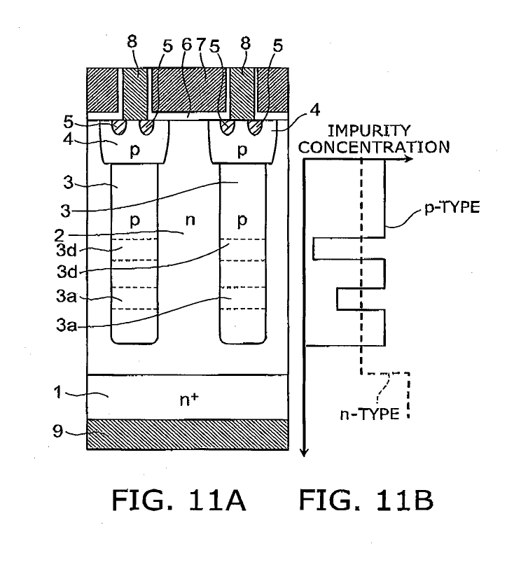

Thus, the more proximal to the drain electrode 9, the more readily depletion occurs; and the more proximal to the source electrode 8, the less readily depletion occurs. Therefore, as illustrated in FIGS. 11A and 11B, it is favorable that the p⁻ region 3d proximal to the source electrode 8 has a lower impurity concentration than that of the p⁻ region 3a proximal to the drain electrode 9.

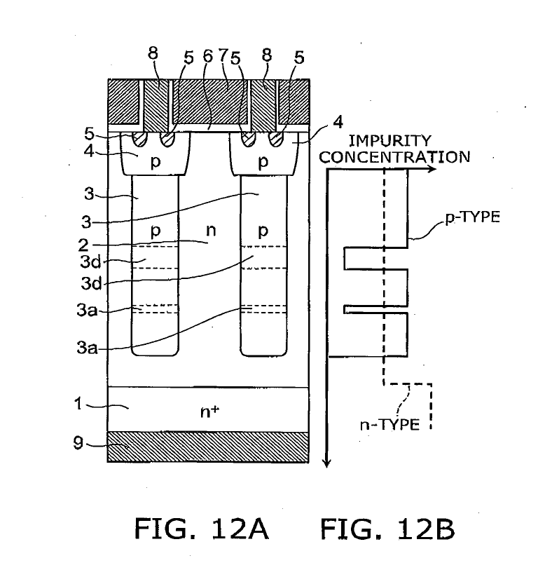

As illustrated in FIGS. 12A and 12B, a similar effect can be obtained by a p⁻ region 3d proximal to the source electrode 8 that is thicker than a p⁻ region 3a proximal to the drain electrode 9.

FIG. 10A to FIG. 12B illustrate examples where p⁻ regions having locally low impurity concentrations are formed in two locations; but three or more locations also may be used. It is favorable that, in such cases for multiple p⁻ regions, the more proximal a p⁻ region is to the source electrode 8 side, the lower its impurity concentration; or the more proximal a p⁻ region is to the source electrode 8 side, the thicker it becomes.

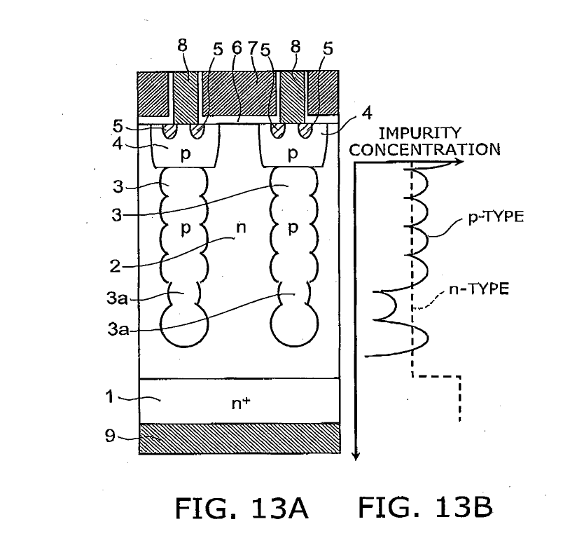

A semiconductor device illustrated in FIG. 13A to FIG. 18B is described hereinbelow and includes a p-type pillar layer 3 or both p-type and n-type pillar layers 3 and 2, formed by crystal growth of an n-type semiconductor layer or a high resistance semiconductor layer on a major surface of the drain layer 1, ion implantation of impurities of the desired conductivity type in the surface thereof, and then repeating the crystal growth process of the n-type semiconductor layer or the high resistance semiconductor layer. Both p-type and n-type pillar layers 3 and 2 can be formed also by a multi-stage ion implantation process having multiple changes of the acceleration voltage.

P-type pillar layers 3 and n-type pillar layers 2 formed by such processes exhibit multiple impurity concentration peaks in the depth direction (drawing B in each of FIG. 13 to FIG. 18) and are formed in wavy shapes (drawing A in each of the same).

### Fourth Embodiment

FIG. 13A is a cross-sectional view of main components of a semiconductor device according to a fourth embodiment of the present invention. FIG. 13B is an impurity concentration profile along the vertical direction (depth direction) of the portion illustrated in FIG. 13A. In FIG. 13B, the solid line represents a concentration profile of the p-type impurity; and the broken line represents a concentration profile of the n-type impurity.

The impurity concentration of the p-type pillar layer 3 can be controlled by controlling the ion implantation amount of the process described above. Accordingly, assuming that the first ion implantation forms the lowermost layer, a lower ion implantation amount may be used during, for example, the second implantation in the example illustrated in FIGS. 13A and 13B. Thus, a p⁻ region 3a having a locally low impurity concentration can be formed in the p-type pillar layer 3.

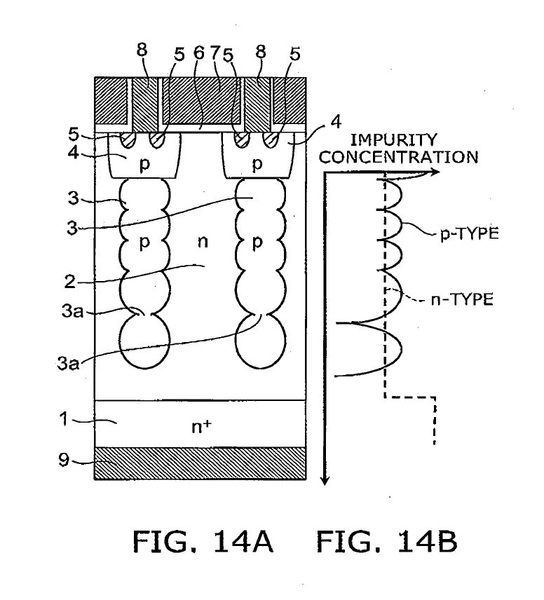

The impurities implanted by ion implantation are diffused by heat treatment after the implantation. Portions that diffuse in the vertical direction connect to one another, and the p-type pillar layer 3 is formed. Accordingly, as illustrated in FIGS. 14A and 14B, portions in which the impurity diffusion regions are difficult to connect in the vertical direction can be formed at the lower layer side by making the thickness of the buried growth layer at the lower layer side greater than that of the upper layer side. Thus, a p⁻ region 3a having a locally low impurity concentration can be formed in the p-type pillar layer 3.

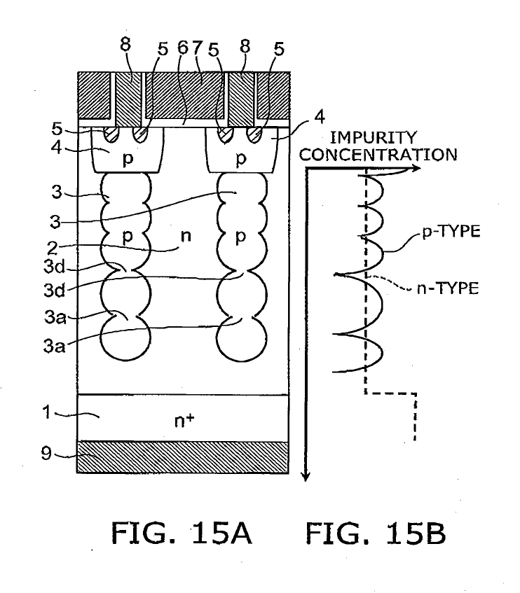

As illustrated in FIGS. 15A and 15B, the thickness of the buried growth layer may be adjusted to form portions of diffusion regions that are difficult to connect (i.e., p⁻ regions 3a and 3d) at multiple locations.

As described in the third embodiment recited above, the more proximal to the source electrode 8, the more difficult depletion becomes. Accordingly, in the structure of FIG. 15A, to make the impurity concentration of the p⁻ region 3d proximal to the source electrode 8 lower than that of the p⁻ region 3a proximal to the drain electrode 9, it is favorable to control the process such that the spacing between positions of the impurity concentration peaks second and third from the bottom is larger than the spacing between positions of the lowermost layer impurity concentration peak and the impurity concentration peak second from the bottom.

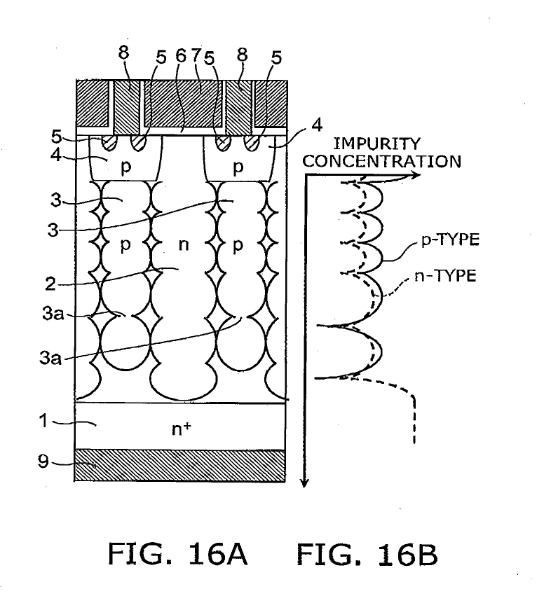

As illustrated in FIGS. 16A and 16B, the n-type pillar layer 2 also may be formed by repeating a process of crystal growth of a buried layer and ion implantation. In other words, the n-type pillar layer 2 also may include multiple impurity concentration peaks in the depth direction, and may be formed in a wavy shape.

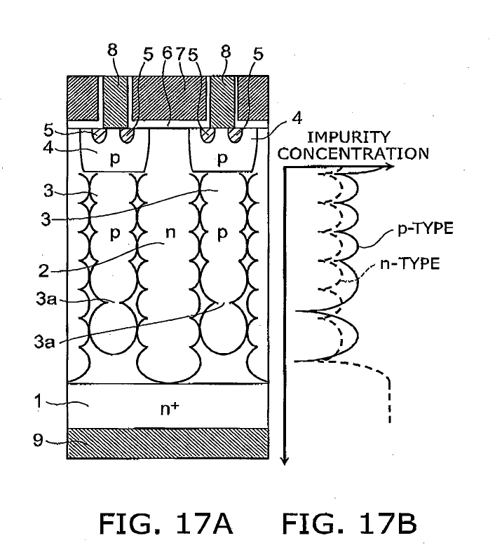

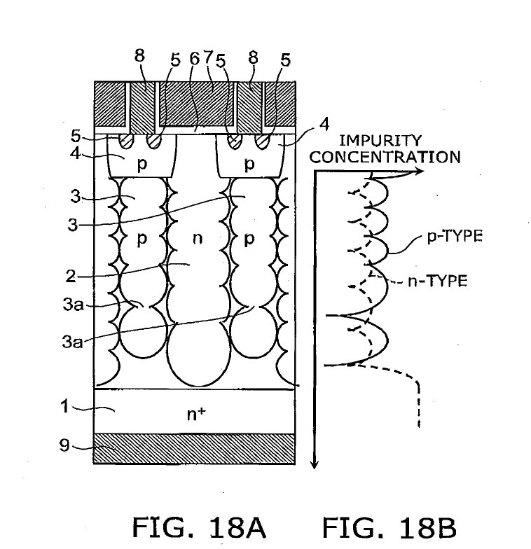

Thus, as illustrated in FIGS. 17A and 17B and FIGS. 18A and 18B, neither the p-type impurity nor the n-type impurity may be implanted in a buried growth layer, or only one thereof may be implanted, such that the implantation position of the p-type impurity and the implantation position of the n-type impurity are shifted in the depth direction; and such that the positions of the impurity concentration peaks of the p-type pillar layer 3 and the impurity concentration peaks of the n-type pillar layer 2 are shifted in the depth direction. By making the impurity concentration of the n-type pillar layer 2 high at the portions where the impurity concentration of the p-type pillar layer 3 is low, the p-type pillar layer 3 can deplete more readily. Thereby, pinch off of the n-type pillar layer 2 is inhibited, and a high operating current density is possible.

### Fifth Embodiment

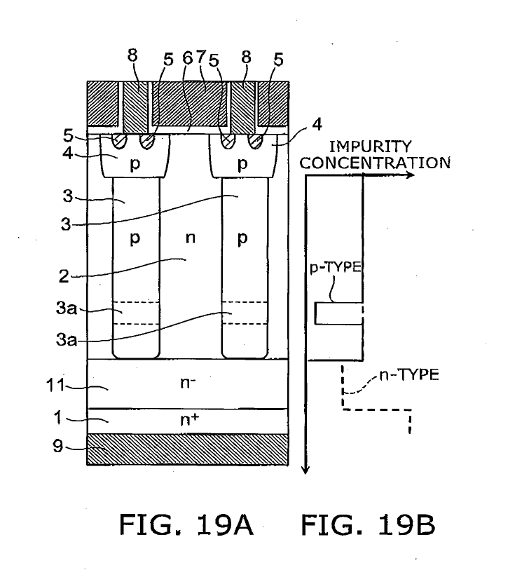

FIG. 19A is a cross-sectional view of main components of a semiconductor device according to a fifth embodiment of the present invention. FIG. 19B is an impurity concentration profile along the vertical direction (depth direction) of the portion illustrated in FIG. 19A. In FIG. 19B, the solid line represents a concentration profile of the p-type impurity; and the broken line represents a concentration profile of the n-type impurity.

In the structure illustrated in FIG. 19A, an n⁻-type drift layer 11 is provided between the drain layer 1 and the super junction structure (the n-type pillar layer 2 and the p-type pillar layer 3). The breakdown voltage can be held also by the drift layer 11, and a higher breakdown voltage can be realized. To increase the holding voltage by the drift layer 11, it is favorable that the impurity concentration of the drift layer 11 is lower than the impurity concentration of the n-type pillar layer 2.

### Sixth Embodiment

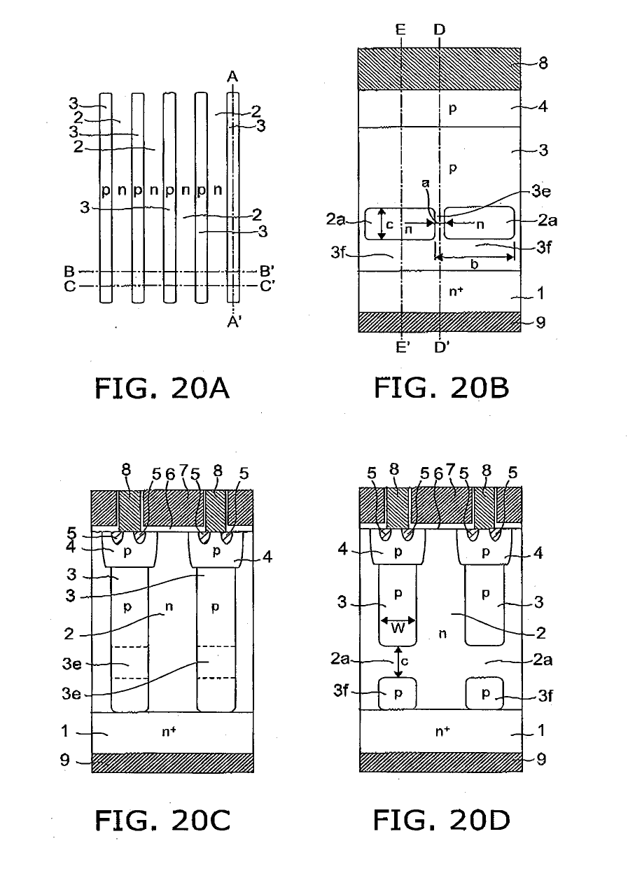

FIG. 20A is a top view illustrating a planar layout of the n-type pillar layer 2 and the p-type pillar layer 3 of a semiconductor device according to a sixth embodiment of the present invention. As illustrated in FIG. 20A, the n-type pillar layer 2 and the p-type pillar layer 3 are formed in a striped planar pattern.

FIG. 20B is a cross-sectional view along A-A′ of FIG. 20A. FIG. 20C is a cross-sectional view along B-B′ of FIG. 20A. FIG. 20D is a cross-sectional view along C-C′ of FIG. 20A. FIG. 20C also is a cross-sectional view along D-D′ of FIG. 20B. FIG. 20D also is a cross-sectional view along E-E′ of FIG. 20B.

The structure illustrated in FIG. 20C and the structure illustrated in FIG. 20D are repeated periodically along the stripe extension direction of the p-type pillar layer 3. This period corresponds to a period b of FIG. 20B.

The p-type pillar layer 3 is divided in the depth direction at a portion intermediate along the depth direction by the n-type pillar layer 2, providing a portion where the p-type pillar layer 3 partially does not exist. The portion where the p-type pillar layer 3 is divided and partially does not exist repeats along the stripe extension direction of the p-type pillar layer 3 at the period b illustrated in FIG. 20B. A thin portion 3e of the p-type pillar layer 3 exists periodically along the stripe extension direction between the regions by which the p-type pillar layer 3 is divided to provide a portion 2a of the n-type pillar layer 2. The portion 3e is thin and therefore completely depletes at a voltage not more than one third of the voltage at which other portions of the p-type pillar layer 3 completely deplete.

In the structure of this embodiment, the thin portion 3e of the p-type pillar layer 3 depletes prior to the n-type pillar layer 2 as the drain voltage is increased in the ON state. Complete depletion of the portion 3e divides the p-type pillar layer 3 in the vertical direction (depth direction) throughout all regions. In other words, the source potential of the p-type pillar layer 3 is divided in the vertical direction; the potential difference between a lower portion 3f of the p-type pillar layer, which is on the lower side of the portion 3e, and the n-type pillar layer 2 is reduced; and extension of the depletion layer toward the n-type pillar layer 2 is inhibited, As a result, pinch off of the n-type pillar layer 2 can be inhibited, and a high operating current density can be realized.

For the portion 3e recited above to deplete at a low voltage, it is favorable to set a width a of the portion 3e from one fortieth to one half of the period b illustrated in FIG. 20B.

Additionally, in the case where the portion 3e recited above is thick, its depletion does not readily occur. Therefore, it is favorable to set a thickness c of the portion 3e from 0.5 to 1 times the width W of the p-type pillar layer 3. Here, the width W is the width orthogonal to the stripe extension direction recited above.

Hereinabove, embodiments of the present invention are described with reference to specific examples. However, the present invention is not limited thereto; and various modifications are possible within the spirit of the present invention.

For example, in the embodiments described above, the description assumes that the first conductivity type is the n-type, and the second conductivity type is the p-type; but the present invention can be practiced also when the first conductivity type is the p-type and the second conductivity type is the n-type.

Furthermore, the planar pattern of the MOS gate portion and the super junction structure are not limited to a striped configuration, and may be formed in a lattice configuration or a staggered configuration. The cross-sectional structure of a planar gate structure is illustrated above; but a trench gate structure also may be used.

Although the structure of the device terminal section is not stated in particular, any terminal structure such as a field plate structure, RESURF (Reduced SURface Field) structure, guard ring structure, and the like may be used without affecting the practice of the present invention.

A process is illustrated above in which crystal growth and ion implantation undergo multiple repetitions to form a super junction structure; but the present invention may be practiced also by a process that performs multiple ion implantations while changing the acceleration voltage; and any process may be used as long as the impurity concentration profiles recited above can be obtained.

Silicon (Si) is used as the semiconductor described above; but compound semiconductors such as silicon carbide (SiC) and gallium nitride (GaN), and wide bandgap semiconductors such as diamond also may be used.

Application of the present invention is not limited to MOSFETs; and as long as the structure includes a device having a super junction structure, the present invention may be applied also to devices such as an SBD (Schottky Barrier Diode), a hybrid device having an SBD and a MOSFET, an SIT (Static Induction Transistor), an IGBT (Insulated Gate Bipolar Transistor), etc.

1. A semiconductor device comprising;
a first semiconductor layer of a first conductivity type;
a second semiconductor layer of the first conductivity type provided on a major surface of the first semiconductor layer;
a third semiconductor layer of a second conductivity type provided adjacent to the second semiconductor layer on the major surface of the first semiconductor layer, the third semiconductor layer forming a structure of periodical arrangement with the second semiconductor layer along a horizontal direction substantially parallel to the major surface of the first semiconductor layer;
a fourth semiconductor layer of the second conductivity type provided above the third semiconductor layer;
a fifth semiconductor layer of the first conductivity type selectively provided on a surface of the fourth semiconductor layer;
a first main electrode electrically connected to the first semiconductor layer;
a second main electrode provided to contact a surface of the fifth semiconductor layer and a surface of the fourth semiconductor layer; and
a control electrode provided above the fifth semiconductor layer, the fourth semiconductor layer, and the second semiconductor layer via an insulative film,
a portion being provided locally in the third semiconductor layer, the portion depleting at a voltage not more than one third of a voltage at which the second semiconductor layer and the third semiconductor layer completely deplete.

2. The device according to claim 1, wherein an impurity concentration of the portion is lower than an impurity concentration of another portion of the third semiconductor layer.

3. The device according to claim 1, wherein the portion comprises a width that is locally narrower than that of another portion of the third semiconductor layer.

4. The device according to claim 1, wherein the portion is at a position that is more proximal, than a portion central along a depth direction of the third semiconductor layer, to the first main electrode.

5. The device according to claim 4, wherein, in the third semiconductor layer, a portion on the second main electrode side of the portion comprises a higher impurity concentration than an impurity concentration of the second semiconductor layer.

6. The device according to claim 5, wherein, in the third semiconductor layer, a portion on the first main electrode side of the portion comprises a higher impurity concentration than an impurity concentration of the second semiconductor layer.

7. The device according to claim 1, wherein, in the second semiconductor layer, a portion on the first main electrode side of the portion of the third semiconductor layer comprises a higher impurity concentration than an impurity concentration of a portion provided on the second main electrode side of the portion of the third semiconductor layer.

8. The device according to claim 1, wherein a plurality of the portions of the third semiconductor layer are separated in a depth direction.

9. The device according to claim 8, wherein the more a portion of the plurality of the portions is proximal to the second main electrode, the more an impurity concentration of the portion decreases.

10. The device according to claim 8, wherein the more a portion of the plurality of the portions is proximal to the second main electrode, the more a thickness of the portion increases.

11. The device according to claim 1, wherein the third semiconductor layer comprises a wavy shape comprising a plurality of impurity concentration peaks in a depth direction.

12. The device according to claim 11, wherein the second semiconductor layer comprises a wavy shape comprising a plurality of impurity concentration peaks in the depth direction.

13. The device according to claim 12, wherein an impurity concentration peak of the third semiconductor layer and an impurity concentration peak of the second semiconductor layer are at different depths.

14. The device according to claim 11, wherein the more impurity concentration peaks of the third semiconductor layer are proximal to the first main electrode, the more a spacing of the depth direction between the peaks increases.

15. The device according to claim 1, wherein an impurity concentration of the portion of the third semiconductor layer is one fortieth to one half of an impurity concentration of another portion of the third semiconductor layer.

16. The device according to claim 1, wherein a thickness of the portion of the third semiconductor layer is from 0.5 to 1 times a width of the third semiconductor layer.

17. The device according to claim 1, wherein a sixth semiconductor layer of the first conductivity type is provided between the first semiconductor layer and the structure of periodical arrangement and comprises an impurity concentration lower than that of the second semiconductor layer.

18. A semiconductor device comprising:
a first semiconductor layer of a first conductivity type;
a second semiconductor layer of the first conductivity type provided on a major surface of the first semiconductor layer;
a third semiconductor layer of a second conductivity type provided adjacent to the second semiconductor layer on the major surface of the first semiconductor layer, the third semiconductor layer forming a structure of periodical arrangement with the second semiconductor layer along a horizontal direction substantially parallel to the major surface of the first semiconductor layer;
a fourth semiconductor layer of the second conductivity type provided above the third semiconductor layer;
a fifth semiconductor layer of the first conductivity type selectively provided on a surface of the fourth semiconductor layer;
a first main electrode electrically connected to the first semiconductor layer;
a second main electrode provided to contact a surface of the fifth semiconductor layer and a surface of the fourth semiconductor layer; and
a control electrode provided above the fifth semiconductor layer, the fourth semiconductor layer, and the second semiconductor layer via an insulative film,
the third semiconductor layer being formed in a striped planar pattern; and
the third semiconductor layer being divided in a depth direction at a portion intermediate along the depth direction by the second semiconductor layer to provide a portion where the third semiconductor layer partially does not exist.

19. The device according to claim 18, wherein a is from one fortieth to one half of b, where a is a width of the third semiconductor layer between portions of the second semiconductor layer that divide the third semiconductor layer in the depth direction, and b is an arrangement period, along an extension direction of the stripe, of the divided portion of the third semiconductor layer.

20. The device according to claim 18, wherein c is 0.5 to 1 times W, where c is a thickness of a portion in which the third semiconductor layer partially is not provided, and W is a width of the third semiconductor layer in a direction orthogonal to an extension direction of the stripe.
